(19) United States
(12) Patent Application Publication
(10) Pub. No.: US 2025/0271156 A1
(43) Pub. Date: Aug. 28, 2025

(54) SUBSTRATE PROCESSING APPARATUS

(71) Applicant: Tokyo Electron Limited, Tokyo (JP)

(72) Inventors: Nobuhiro MATSUYAMA, Oshu City (JP); Koichi SHIMADA, Oshu City (JP); Takashi YOSHIDA, Oshu City (JP); Tomoshi TANIYAMA, Oshu City (JP)

(21) Appl. No.: 19/058,679

(22) Filed: Feb. 20, 2025

(30) Foreign Application Priority Data
Feb. 22, 2024 (JP) 2024-025072
Dec. 27, 2024 (JP) 2024-231971

(51) Int. Cl. F24F 7/04

(52) U.S. Cl. CPC F24F 7/04

(57) ABSTRACT

A substrate processing apparatus includes a reaction tube having a first pipe axis extending in a vertical direction, a vacuum pipe provided to be spaced horizontally apart from the reaction tube and having a second pipe axis parallel to the first pipe axis, an exhaust duct having a flow path configured to bring an interior of the reaction tube into communication with an interior of the vacuum pipe, and a housing configured to accommodate the reaction tube, the vacuum pipe, and the exhaust duct therein.

### CROSS-REFERENCE TO RELATED APPLICATIONS

This application is based upon and claims the benefit of priority from Japanese Patent Application Nos. 2024-025072 and 2024-231971, filed on Feb. 22, 2024 and Dec. 27, 2024, respectively, the entire contents of which are incorporated herein by reference.

### TECHNICAL FIELD

The present disclosure relates to a substrate processing apparatus.

### BACKGROUND

A batch-type substrate processing apparatus that processes a plurality of substrates at once is known (see, for example, Patent Documents 1 and 2). In Patent Document 1, a gas supplied into an inner tube passes through a gap between the inner tube and an outer tube and is exhausted from an exhaust tube located below the outer tube. In Patent Document 2, a gas introduction pipe and a gas exhaust pipe are provided on a side surface of a reaction tube so as to face each other.

### PRIOR ART DOCUMENTS

### Patent Documents

Patent Document 1: Japanese Laid-Open Patent Publication No. 2020-013967

Patent Document 2: Japanese Laid-Open Patent Publication No. 2008-172205

### SUMMARY

According to one embodiment of the present disclosure, a substrate processing apparatus includes a reaction tube having a first pipe axis extending in a vertical direction, a vacuum pipe provided to be spaced horizontally apart from the reaction tube and having a second pipe axis parallel to the first pipe axis, an exhaust duct having a flow path configured to bring an interior of the reaction tube into communication with an interior of the vacuum pipe, and a housing configured to accommodate the reaction tube, the vacuum pipe, and the exhaust duct therein.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a perspective view (1) showing a substrate processing apparatus according to an embodiment.

FIG. 2 is a perspective view (2) showing the substrate processing apparatus according to the embodiment.

FIG. 3 is a vertical cross-sectional view showing the substrate processing apparatus according to the embodiment.

FIG. 4 is a horizontal cross-sectional view (1) showing the substrate processing apparatus according to the embodiment.

FIG. 5 is a horizontal cross-sectional view (2) showing the substrate processing apparatus according to the embodiment.

FIG. 6 is a view showing an example of an exhaust duct.

FIG. 7 is a view showing a simulation result of a gas flow velocity distribution in a vertical direction inside a reaction tube.

### DETAILED DESCRIPTION

Hereinafter, a non-limiting exemplary embodiment of the present disclosure will be described with reference to the accompanying drawings. In all of the accompanying drawings, the same or corresponding members or parts are designated by the same or corresponding reference numerals, and duplicate descriptions thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Substrate Processing Apparatus

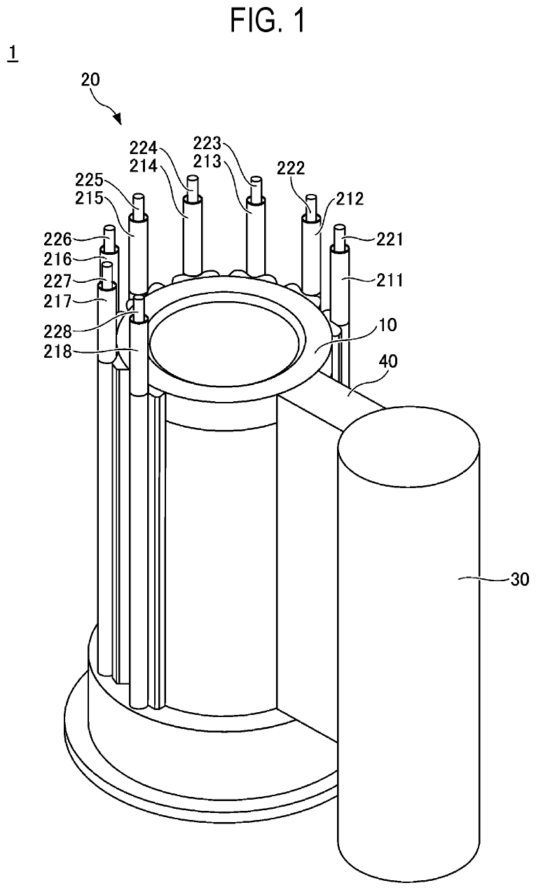

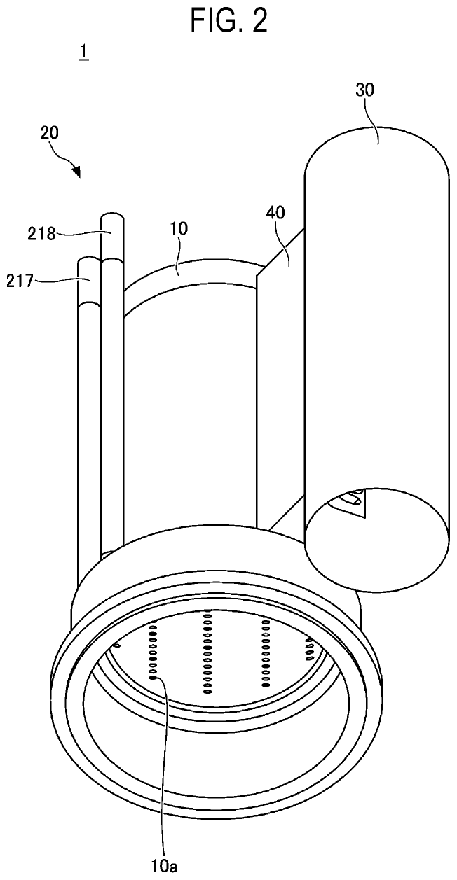

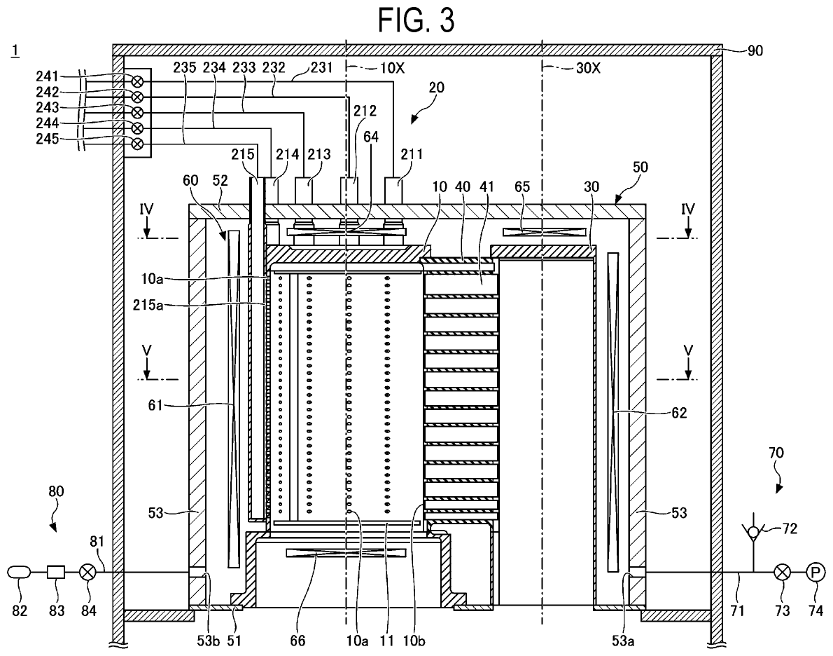

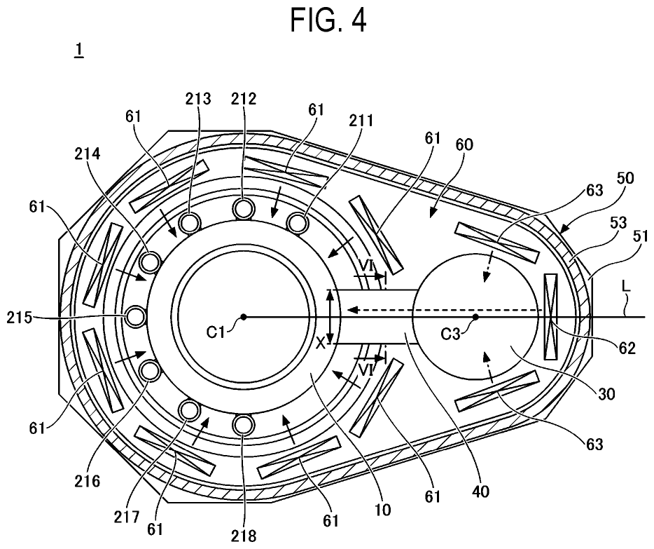

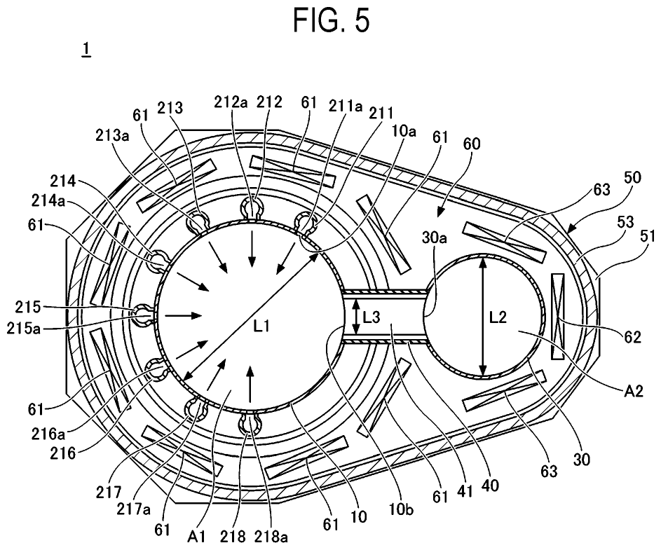

A substrate processing apparatus 1 according to an embodiment will be described with reference to FIGS. 1 to 5. FIG. 1 is a perspective view showing the substrate processing apparatus 1 according to an embodiment, when obliquely viewed from above. FIG. 2 is a perspective view showing the substrate processing apparatus 1 according to the embodiment, when obliquely viewed from below. FIG. 3 is a vertical cross-sectional view showing the substrate processing apparatus 1 according to the embodiment. FIG. 4 is a horizontal cross-sectional view showing the substrate processing apparatus 1 according to the embodiment and taken along line IV-IV in FIG. 3. FIG. 5 is a horizontal cross-sectional view showing the substrate processing apparatus 1 according to the embodiment and taken along line V-V in FIG. 3.

The substrate processing apparatus 1 is a batch-type apparatus that collectively performs various processes on a plurality of substrates W. The various processes include a film formation process for forming a film on the substrate W by, for example, atomic layer deposition (ALD) or chemical vapor deposition (CVD). The various processes may also include an etching process for removing a film formed on the substrate W.

The substrate processing apparatus 1 includes a reaction tube 10, a gas introducer 20, a vacuum pipe 30, an exhaust duct 40, a housing 50, a heater 60, a depressurizer 70, a pressurizer 80, and an apparatus housing 90. In FIGS. 1 and 2, the housing 50, the heater 60, the depressurizer 70, the pressurizer 80, and the apparatus housing 90 are not shown. The reaction tube 10, the vacuum pipe 30, and the exhaust duct 40 are bonded to each other by, for example, welding, and are formed integrally with each other. The reaction tube 10, the vacuum pipe 30, and the exhaust duct 40 are made of, for example, quartz.

The reaction tube 10 has a pipe axis 10X extending in the vertical direction. The pipe axis 10X is an example of a first pipe axis. The reaction tube 10 has a roof in a cylindrical shape and an open lower end. Introduction openings 10a and an exhaust opening 10b are provided in an outer wall of the reaction tube 10.

The introduction openings 10a penetrate the outer wall of the reaction tube 10. The introduction openings 10a are provided at positions in a circumferential direction of the reaction tube 10 where gas introduction ducts 211 to 218 (to be described later) are attached. The introduction openings 10a are provided along a vertical direction from the vicinity of an upper end to the vicinity of the lower end of the reaction tube 10 at respective positions in the circumferential direction of the reaction tube 10. In this case, it is easy to uniformly supply a gas to a range from the upper end to the lower end inside the reaction tube 10.

The exhaust opening 10b penetrates the outer wall of the reaction tube 10. The exhaust opening 10b is provided at a position different from the introduction openings 10a in the circumferential direction of the reaction tube 10. The exhaust opening 10b is provided at a position where the exhaust duct 40 is attached in the circumferential direction of the reaction tube 10. The exhaust opening 10b is a rectangular opening extending vertically from the vicinity of the upper end to the vicinity of the lower end of the reaction tube 10. In this case, it is easy to uniformly exhaust a gas over a range from the upper end to the lower end inside the reaction tube 10.

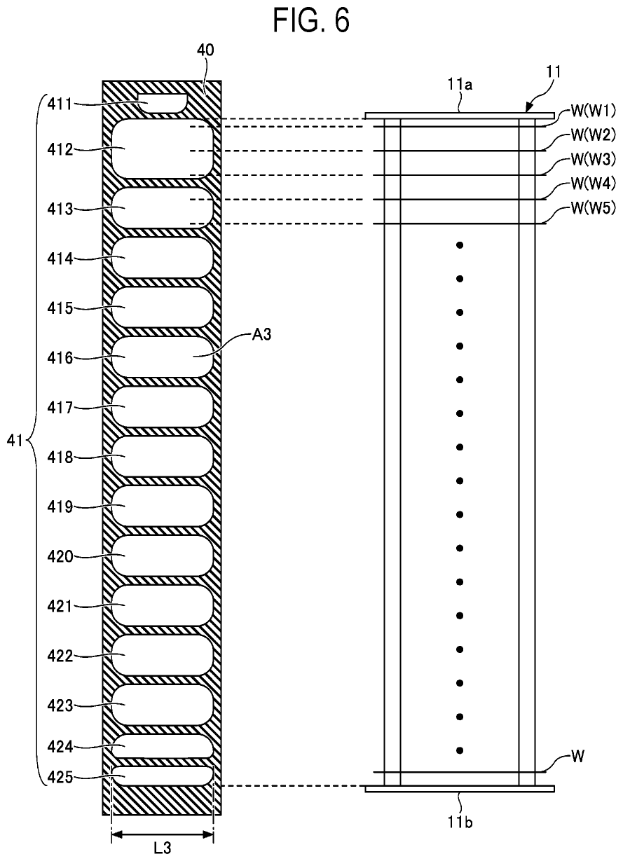

The opening at the bottom end of the reaction tube 10 is air-tightly closed by a lid (not shown). The lid is made of, for example, a metal such as stainless steel or the like. A substrate holder 11 (FIG. 3) is accommodated in the reaction tube 10. The substrate holder 11 holds the plurality of substrates W (FIG. 6) arranged in a horizontal posture and in multiple stages in the vertical direction. The number of substrates W is not limited, but may be, for example, 25 to 200. The substrates W are not shown in FIG. 3. The substrate holder 11 is made of, for example, quartz.

The gas introducer 20 includes gas introduction ducts 211 to 218, nozzles 221 to 228, gas introduction pipes 231 to 238, and opening/closing valves 241 to 248. In FIG. 3, the gas introduction pipes 231 to 235 and the opening/closing valves 241 to 245 are shown.

The gas introduction ducts 211 to 218 are provided along the circumferential direction of the reaction tube 10. The gas introduction ducts 211 to 218 are provided to be spaced apart from each other in the circumferential direction of the reaction tube 10. In this case, the thermal influence from adjacent gas introduction ducts 211 to 218 may be reduced. This makes it possible to suppress a temperature drop in the gas introduction ducts 211 to 218 and suppress the generation of particles. The gas introduction ducts 211 to 218 are provided radially at intervals from each other in the circumferential direction of the reaction tube 10. In this case, as indicated by arrows in FIG. 5, gases such as a raw material gas, a reaction gas, an etching gas, and a purge gas may be supplied into the reaction tube 10 from multiple positions (multiple directions) in the circumferential direction of the reaction tube 10. Therefore, an in-plane shape in the film formation process or the etching process may be easily adjusted. For example, by adjusting a gas supply position and a gas supply amount, a gas staying time and gas concentration distribution of the gases supplied to the surfaces of the substrates W may be adjusted. Therefore, it is easier to control the in-plane shape in the film formation process or the etching process than in a case where the gases flow in one direction. The gas introduction ducts 211 to 218 are provided in the named order, for example, counterclockwise from the exhaust opening 10b.

The gas introduction ducts 211 to 218 are attached to the outer wall of the reaction tube 10. In this case, distances from the gas introduction ducts 211 to 218 to the substrates W are shortened. This makes it possible to suppress unnecessary thermal decomposition of gases. Further, in the case in which the gas introduction ducts 211 to 218 are attached to the outer wall of the reaction tube 10, it is not necessary to arrange the nozzles 221 to 228 inside the reaction tube 10. Therefore, a space between outer peripheral ends of the substrates W and an inner wall of the reaction tube 10 may be narrowed. This suppresses the flow of gases into the space. As a result, the efficiency of supplying the gases between the substrates W adjacent to each other in the vertical direction is improved. Further, in the case in which the gas introduction ducts 211 to 218 are attached to the outer wall of the reaction tube 10, it is not necessary to form a nozzle chamber for accommodating the nozzles 221 to 228, which may otherwise be formed by protruding a sidewall of the reaction tube 10 outward in the radial direction. The gas introduction ducts 211 to 218 are formed integrally with, for example, the reaction tube 10. The gas introduction ducts 211 to 218 are made of, for example, quartz.

Each of the gas introduction ducts 211-218 has a tubular shape with a closed lower end and an open upper end. The upper ends of the gas introduction ducts 211 to 218 extend above the upper surface of the reaction tube 10 and penetrate the housing 50. In this case, an upper space of the housing 50 may be used as a space in which the gas introduction pipes 231 to 238 and the opening/closing valves 241 to 248 are installed. Therefore, a piping distance from the opening/closing valves 241 to 248 to the reaction tube 10 may be shortened. In addition, the shape of the gas introduction pipes 231-238 may be simplified. Gas holes 211a to 218a (FIG. 5) are provided at positions of the gas introduction ducts 211 to 218 facing the reaction tube 10.

Each of the gas holes 211a to 218a has, for example, a rectangular shape extending vertically from the vicinity of the upper end to the vicinity of the lower end of the reaction tube 10. Each of the gas holes 211a to 218a extends, for example, from above the uppermost introduction opening 10a to below the lowermost introduction opening 10a. The gases flowing through interiors of the gas introduction ducts 211 to 218 are discharged into the reaction tube 10 via the gas holes 211a to 218a.

The gas introduction duct 211 is provided in an angular range of less than 90° counterclockwise from the exhaust duct 40 in the circumferential direction of the reaction tube 10. The gas introduction duct 212 is provided at an angular position of 90° counterclockwise from the exhaust duct 40 in the circumferential direction of the reaction tube 10. The gas introduction ducts 213 and 214 are provided in an angular range of more than 90° and less than 180° counterclockwise from the exhaust duct 40. The gas introduction duct 215 is provided at an angular position of 180° counterclockwise from the exhaust duct 40 in the circumferential direction of the reaction tube 10. That is, the gas introduction duct 215 is provided at a position facing the exhaust duct 40. The gas introduction ducts 216 and 217 are provided in an angular range of more than 180° and less than 270° counterclockwise from the exhaust duct 40. The gas introduction duct 218 is provided at an angular position of 270° counterclockwise from the exhaust duct 40. In other words, the gas introduction duct 218 is provided at a position facing the gas introduction duct 212.

The nozzles 221 to 228 are detachably inserted into the gas introduction ducts 211 to 218. In this case, shapes or the like of the nozzles 221 to 228 may be changed depending on the type of processing. The nozzles 221 to 228 optimized for the type of processing may be used. An inner surface of each of the gas introduction ducts 211 to 218 has a shape conforming to, for example, outer surfaces of the nozzles 221 to 228. A gap is provided between the inner surface of each of the gas introduction ducts 211-218 and the outer surfaces of the nozzles 221 to 228. In this case, a volume of a space between the gas introduction ducts 211 to 218 and the nozzles 221 to 228 may be reduced. Therefore, the stagnation of the gases in the space is suppressed, and the efficiency of supplying the gases to the substrates W is improved. In addition, a surface area in contact with the gases is reduced. This suppresses the generation of particles in the space. Therefore, the space may be easily cleaned. In a cross section perpendicular to a longitudinal direction of the nozzles 221 to 228, the inner surface of each of the gas introduction ducts 211 to 218 is, for example, circular, and the outer surface of each of the nozzles 221 to 228 is, for example, circular. In a cross section perpendicular to the longitudinal direction of the nozzles 221 to 228, the inner surface of each of the gas introduction ducts 211 to 218 may be, for example, elliptical, and the outer surface of each of the nozzles 221-228 may be, for example, elliptical.

The nozzles 221 to 228 are provided with gas discharge holes (not shown). The gas discharge holes are provided in, for example, portions of the pipe walls of the nozzles 221 to 228 that are inserted into the gas introduction ducts 211 to 218. The upper ends of the nozzles 221 to 228 are connected to gas sources (not shown) via the corresponding gas introduction pipes 231 to 238. Gases from the gas sources are introduced into the nozzles 221 to 228 from the upper ends thereof, and are discharged into the reaction tube 10 via the gas discharge holes, the gas holes 211a to 218a, and the introduction opening 10a. In FIG. 2 to FIG. 5, the nozzles 221 to 228 are not shown.

The nozzles 221 to 228 may be omitted. In this case, the upper ends of the gas introduction ducts 211 to 218 are connected to the gas sources via the corresponding gas introduction pipes 231 to 238. Gases from the gas sources are introduced into the gas introduction ducts 211 to 218 from the upper ends thereof, and are discharged into the reaction tube 10 via the gas holes 211a to 218a. For example, when a gas that is easy to thermally decompose, such as a hexachlorodisilane (HCD) gas, a dichlorosilane (DCS) gas, or the like, is used, the nozzles 221 to 228 may be omitted.

The gas introduction pipes 231 to 238 are provided in the upper space of the housing 50. One end of each of the gas introduction pipes 231 to 238 is connected to the corresponding one of the gas introduction ducts 211 to 218 or the corresponding one of the nozzles 221 to 228, and the other end thereof passes through the apparatus housing 90 and extends outward of the apparatus housing 90. The gas introduction pipes 231 to 238 are provided with opening/closing valves 241 to 248. Each of the gas introduction pipes 231 to 238 may be provided with a flow rate controller such as a mass flow controller or the like.

The opening/closing valves 241 to 248 are provided in the upper space of the housing 50. The opening/closing valves 241 to 248 are provided in the middle of the corresponding gas introduction pipes 231 to 238. The opening/closing valves 241 to 248 are attached to, for example, an inner wall of the apparatus housing 90. Each of the opening/closing valves 241 to 248 is a valve that switches the on/off state of a gas flow.

The vacuum pipe 30 has a pipe axis 30X extending in the vertical direction. The pipe axis 30X is an example of a second pipe axis. The vacuum pipe 30 has a roof in a cylindrical shape and an open lower end. A cross-sectional shape of the vacuum pipe 30 in the horizontal cross section is a circle. However, the cross-sectional shape of the vacuum pipe 30 in the horizontal cross section may be a rectangle or an ellipse. The vacuum pipe 30 is provided to be spaced apart horizontally from the reaction tube 10. The vacuum pipe 30 is provided adjacent to the reaction tube 10. The vacuum pipe 30 is provided at substantially the same height as the reaction tube 10. An opening 30a (FIG. 5) is provided in an outer wall of the vacuum pipe 30 at the same position as the exhaust duct 40 in the circumferential direction of the vacuum pipe 30. The opening 30a is a rectangular opening extending vertically from the vicinity of the upper end to the vicinity of the lower end of the vacuum pipe 30. A vertical length of the opening 30a may be the same as a vertical length of the exhaust opening 10b. The pipe axis 30X of the vacuum pipe 30 may be parallel to the pipe axis 10X of the reaction tube 10. The lower end of the vacuum pipe 30 is connected to an exhaust device (not shown) such as a vacuum pump or the like via a pipe (not shown).

A flow path cross-sectional area A2 (FIG. 5) of the vacuum pipe 30 may be 0.7 times or more a flow path cross-sectional area A3 (FIG. 6) of the exhaust duct 40. In this case, an exhaust flow velocity in the vertical direction is likely to be uniform, and therefore a uniform laminar flow in the vertical direction is likely to be formed. This improves an inter-plane uniformity of film formation or etching. The flow path cross-sectional area A2 of the vacuum pipe 30 may be the same as the flow path cross-sectional area A3 of the exhaust duct 40. The flow path cross-sectional area A2 of the vacuum pipe 30 may be larger than the flow path cross-sectional area A3 of the exhaust duct 40. The flow path cross-sectional area A2 of the vacuum pipe 30 may be smaller than the flow path cross-sectional area A1 (FIG. 5) of the reaction tube 10. The flow path cross-sectional area Al of the reaction tube 10 is the cross-sectional area of the reaction tube 10 in the horizontal cross section. The flow path cross-sectional area A2 of the vacuum pipe 30 is the cross-sectional area of the vacuum pipe 30 in the horizontal cross section. The flow passage cross-sectional area A3 of the exhaust duct 40 is the sum of the cross-sectional areas of the divided flow paths 411 to 425 in the vertical cross section. The divided flow paths 411 to 425 will be described later.

In a cross-sectional view (FIG. 5) perpendicular to the pipe axis 10X and the pipe axis 30X, when an inner diameter of the reaction tube 10 is L1, an inner diameter of the vacuum pipe 30 is L2, and a flow path width of the exhaust duct is L3, it is preferable to satisfy a relationship L1>L2>L3. In this case, the exhaust flow velocity in the vertical direction is likely to be uniform, and therefore a uniform laminar flow in the vertical direction is likely to be formed. This improves the inter-plane uniformity of film formation or etching. For example, the inner diameter L1 of the reaction tube 10 is a dimension determined according to a diameter of the substrate W to be processed, and is set in consideration of a clearance when the substrate holder 11 is loaded into the reaction tube 10, a distance between the gas holes 211a to 218a and the substrates W held by the substrate holder 11, and the like. The flow path width L3 of the exhaust duct 40 is set in consideration of, for example, a quality of the processing performed on the substrates W. The quality of the processing includes, for example, the inter-plane uniformity of the processing and the in-plane uniformity of the processing. The flow path width L3 of the exhaust duct 40 may be equal to or larger than ¼ of the inner diameter LI of the reaction tube 10. In this case, it is easy to suppress a decrease in the flow velocity of the gas flowing through the interior of the reaction tube 10. This makes it easy to improve the in-plane uniformity of the processing.

The exhaust duct 40 connects the reaction tube 10 and the vacuum pipe 30. The exhaust duct 40 includes a flow path 41 that brings the interior of the reaction tube 10 and the interior of the vacuum pipe 30 into communication with each other. One end of the exhaust duct 40 is connected to the outer wall of the reaction tube 10 so as to cover the exhaust opening 10b, and the other end thereof is connected to the outer wall of the vacuum pipe 30 so as to cover the opening 30a. In this case, a length X (FIG. 4) occupied by the exhaust duct 40 in the circumferential direction of the reaction tube 10 may be shortened compared to a case where the vacuum pipe 30 is directly connected to the reaction tube 10 without providing the exhaust duct 40. Therefore, the length in the circumferential direction of the reaction tube 10 over which the gas introduction ducts 211 to 218 may be attached is increased. This makes it possible to increase the number of gas introduction ducts 211 to 218 provided on the outer wall of the reaction tube. The exhaust duct 40 may be divided into a plurality of parts in the vertical direction. In this case, the flow of the gas from the interior of the reaction tube 10 toward the vacuum pipe 30 is rectified. This improves the uniformity of the gas flow at different vertical positions in the interior of the reaction tube 10.

The housing 50 accommodates the reaction tube 10, the gas introducer 20, the vacuum pipe 30, the exhaust duct 40, and the heater 60 therein. The housing 50 is also referred to as a heater shell because it accommodates the heater 60 including heaters. The housing 50 has a bottom portion 51, a top portion 52, and a side portion 53. The bottom portion 51 supports the reaction tube 10 and the vacuum pipe 30. The top portion 52 is provided above the upper surface of the reaction tube 10 and the upper surface of the vacuum pipe 30. The top portion 52 covers the upper surface of the reaction tube 10 and the upper surface of the vacuum pipe 30. The side portion 53 is provided around the reaction tube 10, the gas introducer 20, the vacuum pipe 30, and the exhaust duct 40. The side portion 53 covers the reaction tube 10, the gas introducer 20, the vacuum pipe 30, and the exhaust duct 40. The side portion 53 has a lower end connected to the bottom portion 51 and an upper end connected to the top portion 52. The bottom portion 51, the top portion 52, and the side portion 53 are configured as, for example, separate bodies. Alternatively, the bottom portion 51, the top portion 52, and the side portion 53 may be configured as an integral body.

The heater 60 is provided inside the housing 50. The heater 60 includes first side heaters 61, a second side heater 62, third side heaters 63, a first ceiling heater 64, a second ceiling heater 65, and lower heaters 66. The first side heaters 61, the second side heater 62, the third side heaters 63, the first ceiling heater 64, the second ceiling heater 65, and the lower heaters 66 are, for example, carbon wire heaters. In this case, temperatures of the substrates W accommodated in the interior of the reaction tube 10 may be rapidly increased or decreased.

The first side heaters 61 are provided around the reaction tube 10. The first side heaters 61 are provided radially at intervals in the circumferential direction of the reaction tube 10. Each of the first side heaters 61 is provided at a position different from the exhaust duct 40 in the circumferential direction of the reaction tube 10. Each of the first side heaters 61 may be divided into a plurality of heaters in the vertical direction. In this case, the divided first side heaters 61 may be independently controlled to independently adjust the temperature in the vertical direction. The first side heaters 61 heat the substrates W accommodated in the reaction tube 10 from the outside of the reaction tube 10 by thermal radiation, as indicated by the solid arrows in FIG. 4.

The second side heater 62 is provided at a position different from the first side heaters 61 in the circumferential direction of the reaction tube 10. The second side heater 62 is provided at a position different from the gas introduction ducts 211 to 218 in the circumferential direction of the reaction tube 10. The second side heater 62 is provided at a position including the same position as the exhaust duct 40 in the circumferential direction of the reaction tube 10. Since the vacuum pipe 30 is provided around the reaction tube 10 at the same position as the exhaust duct 40 in the circumferential direction of the reaction tube 10, the second side heater 62 cannot be provided. Therefore, the second side heater 62 is provided around the vacuum pipe 30. That is, the second side heater 62 is provided at a position farther from the center C1 of the reaction tube 10 than the first side heaters 61. For example, the second side heater 62 is provided on an imaginary half line L extending from the center C1 of the reaction tube 10 via the center C3 of the vacuum pipe 30 in a plan view. The second side heater 62 may be divided into a plurality of heaters in the vertical direction. In this case, the temperature in the vertical direction may be independently adjusted by independently controlling the plurality of divided second side heaters 62. As indicated by the broken line arrow in FIG. 4, the second side heater 62 heats the vacuum pipe 30 and the exhaust duct 40 by thermal radiation and heats the substrates W accommodated in the reaction tube 10. As a result, the substrates W accommodated in the reaction tube 10 are heated from all directions around the reaction tube 10 by the first side heaters 61 and the second side heater 62. Therefore, the temperature uniformity in the in-plane of the substrate is improved.

The third side heaters 63 are provided around the vacuum pipe 30. The third side heaters 63 are provided at intervals in the circumferential direction of the vacuum pipe 30. Each of the third side heaters 63 is provided at a position different from the second side heater 62 in the circumferential direction of the vacuum pipe 30. Each of the third side heaters 63 is provided so as not to lie on the imaginary half line L in a plan view. Each of the third side heaters 63 may be divided into a plurality of heaters in the vertical direction. In this case, the temperature in the vertical direction may be independently adjusted by independently controlling the divided third side heaters 63. The third side heaters 63 heat the vacuum pipe 30 as indicated by the one-dot chain line arrow in FIG. 4.

The first ceiling heater 64 is provided between the upper surface of the reaction tube 10 and the top portion 52 of the housing 50. The first ceiling heater 64 heats the substrates W accommodated in the reaction tube 10 from above the reaction tube 10 by thermal radiation. The number of the first ceiling heater 64 may be one, or two or more.

The second ceiling heater 65 is provided between the upper surface of the vacuum pipe 30 and the top portion 52 of the housing 50. The second ceiling heater 65 heats the vacuum pipe 30 from above the vacuum pipe 30 by thermal radiation. The number of the second ceiling heater 65 may be one, or two or more.

The lower heaters 66 are provided around the lower portion of the reaction tube 10. The lower heaters 66 are provided radially at intervals in the circumferential direction of the reaction tube 10. The lower heaters 66 are provided below the substrate holder 11. The lower heaters 66 heat the lower portion of the reaction tube 10 by thermal radiation and suppress the radiation of heat from the opening at the lower end of the reaction tube 10.

The depressurizer 70 reduces an internal pressure of the housing 50. The depressurizer 70 includes a pipe 71, a safety valve 72, an opening/closing valve 73, and a vacuum pump 74.

The pipe 71 is connected to a port 53a provided in the side portion 53 of the housing 50. The pipe 71 extends outward of the apparatus housing 90 via the side portion 53 and the apparatus housing 90. The safety valve 72, the opening/closing valve 73, and the vacuum pump 74 are provided in the pipe 71 in the named order from the side of the housing 50. The safety valve 72, the opening/closing valve 73, and the vacuum pump 74 are provided, for example, outside the apparatus housing 90. The safety valve 72, the opening/closing valve 73, and the vacuum pump 74 may be provided outside the housing 50 and inside the apparatus housing 90.

The state of the safety valve 72 is changed from a closed state to an open state when the internal pressure of the housing 50 exceeds a set pressure, thereby maintaining the internal pressure of the housing 50 at or below the set pressure.

The opening/closing valve 73 is a valve that switches the on/off state of a gas flow.

The vacuum pump 74 reduces the internal pressure of the housing 50 via the pipe 71.

When the opening/closing valve 73 is in the open state, the interior of the housing 50 is depressurized by the vacuum pump 74. In the state in which the interior of the housing 50 is depressurized, the transfer of heat by convection is suppressed. This suppresses the transfer of heat to the outside of the housing 50. Thus, the space above the housing 50 may be used as a space for installing the opening/closing valves 241 to 248. In addition, a heat insulating material is not required, and therefore, the distance between the reaction tube 10 and the housing 50 may be shortened. This makes it possible to shorten the distance from the opening/closing valves 241 to 248 to the substrates, and improve the controllability of the gas. Further, when the side heaters (the first side heaters 61, the second side heater 62, and the third side heaters 63) are divided into a plurality of heaters in the vertical direction, there is no influence of convection in the interior of the housing 50, so that the side heaters are less likely to be influenced by other heaters in the vertical direction. Therefore, an inter-plane temperature controllability (in the vertical direction) is improved. This makes it easy to selectively heat only the lower portion of the reaction tube 10, selectively heat only the center of the reaction tube 10, or selectively heat only the upper portion of the reaction tube 10.

The pressurizer 80 returns the internal pressure of the housing 50, which has been depressurized, to an atmospheric pressure. The pressurizer 80 includes a pipe 81, a gas source 82, a flow rate controller 83, and an opening/closing valve 84.

The pipe 81 is connected to a port 53b provided in the side portion 53 of the housing 50. The pipe 81 extends outward of the apparatus housing 90 via the side portion 53 and the apparatus housing 90. The gas source 82, the flow rate controller 83, and the opening/closing valve 84 are provided in the pipe 81 in the named order from the upstream side to the downstream side in a gas flow direction. The gas source 82, the flow rate controller 83, and the opening/closing valve 84 are provided, for example, outside the apparatus housing 90. The gas source 82, the flow rate controller 83, and the opening/closing valve 84 may be provided outside the housing 50 and inside the apparatus housing 90.

The gas source 82 is, for example, a source of an inert gas. The inert gas is, for example, a nitrogen gas. The inert gas may be an argon gas.

The flow rate controller 83 controls a flow rate of the gas flowing through the pipe 81. The flow rate controller 83 is, for example, a mass flow controller.

The opening/closing valve 84 is a valve that switches the on/off state of a gas flow.

When the opening/closing valve 84 is opened, the flow rate of the gas from the gas source 82 is controlled by the flow rate controller 83, and the gas with the controlled flow rate is supplied into the housing 50. As a result, the internal pressure of the housing 50, which has been depressurized, returns to the atmospheric pressure.

The apparatus housing 90 surrounds the housing 50. The apparatus housing 90 covers the entire housing 50. The apparatus housing 90 supports the bottom portion 51 of the housing 50.

As described above, the substrate processing apparatus 1 according to the embodiment includes the reaction tube 10, the vacuum pipe 30, and the exhaust duct 40. The reaction tube 10 has the pipe axis 10X extending in the vertical direction. The vacuum pipe 30 is provided to be horizontally spaced apart from the reaction tube 10 and has the pipe axis 30X parallel to the pipe axis 10X. The exhaust duct 40 includes the flow path 41 that brings the interior of the reaction tube 10 into communication with the interior of the vacuum pipe 30. In this case, the gas inside the reaction tube 10 flows horizontally or substantially horizontally through the flow path 41 of the exhaust duct 40, and is then exhausted via the vacuum pipe 30. Thus, the exhaust gas flow velocity in the vertical direction is likely to be uniform, and therefore, a uniform laminar flow in the vertical direction is easily formed. As a result, the inter-plane uniformity of film formation or etching is improved.

### Exhaust Duct

An example of the exhaust duct 40 will be described with reference to FIG. 6. FIG. 6 is a view showing the example of the exhaust duct 40. The left diagram in FIG. 6 shows a cross section taken along line VI-VI in FIG. 4, and the right diagram in FIG. 6 shows the substrate holder 11.

The exhaust duct 40 includes the flow path 41 including the plurality of divided flow paths 411 to 425. The divided flow paths 411 to 425 are provided at intervals along the vertical direction. In this case, the flow of the gas from the interior of the reaction tube 10 toward the vacuum pipe 30 is rectified. This improves the uniformity of the gas flow at different positions in the vertical direction in the interior of the reaction tube 10.

The divided flow path 411 is provided in a height region above the top plate 11a of the substrate holder 11. The divided flow path 411 mainly exhausts the gas flowing along the upper surface of the top plate 11a. The divided flow path 411 is an example of a first divided flow path. The divided flow paths 412 to 425 are provided in height regions (hereinafter referred to as “substrate holding regions”) below the top plate 11a of the substrate holder 11 and above the bottom plate 11b of the substrate holder 11. The divided flow paths 412 to 425 mainly exhaust the gas flowing along the surfaces of the substrates W held by the substrate holder 11. The divided flow paths 412 to 425 are examples of second divided flow paths.

For example, the divided flow paths 413 to 423 have the same flow path cross-sectional area. In this case, it is easy to improve the uniformity of an exhaust amount in the vertical direction in the substrate holding area.

The flow path cross-sectional area of the divided flow path 411 is smaller than, for example, the flow path cross-sectional area of each of the divided flow paths 413 to 423. In this case, the amount of the gas flowing along the upper surface of the top plate 11a may be reduced so that the amount of the gas flowing into the substrate holding region may be increased. Therefore, the gas introduced into the reaction tube 10 from the gas introducer 20 may be efficiently utilized. The flow path cross-sectional area of the divided flow path 412 may be larger than the flow path cross-sectional area of each of the divided flow paths 413 to 423. The flow path cross-sectional areas of the divided flow paths 424 and 425 may be smaller than the flow path cross-sectional area of each of the divided flow paths 413 to 423.

Each of the substrates W held by the substrate holder 11 may be located at the same height as any of the divided flow paths 412 to 425. In other words, it is preferable that the substrates W are not located at height positions where the divided flow paths 412 to 425 are not provided. In this case, the divided flow paths 412 to 425 may efficiently exhaust the gas flowing along the surface of each of the substrates W. The example of FIG. 6 shows a case where substrates W1, W2, and W3 are located at the same height as the divided flow path 412, and substrates W4 and W5 are located at the same height as the divided flow path 413.

In the example of FIG. 6, there has been described the case in which the exhaust duct 40 has fifteen divided flow paths 411 to 425. However, the number of divided flow paths 411 to 425 is not limited to fifteen. The exhaust duct 40 may have a single flow path instead of the divided flow paths 411 to 425.

### Simulation Results

In the substrate processing apparatus 1 shown in FIGS. 1 to 6, the gas flow velocities at multiple positions along the vertical direction in the reaction tube 10 when a gas is supplied from the gas introducer 20 into the reaction tube 10 and exhausted from the vacuum pipe 30 were calculated by simulation. In this simulation, three-dimensional thermal fluid analysis software was used. In this simulation, the gas flow velocity distributions in the vertical direction in the interior of the reaction tube 10 were compared with each other while a ratio of the flow path cross-sectional area A2 of the vacuum pipe 30 to the flow path cross-sectional area A3 of the exhaust duct 40 is changed and other conditions are kept unchanged. In this simulation, the flow path cross-sectional area A3 of the exhaust duct 40 was fixed and the flow path cross-sectional area A2 of the vacuum pipe 30 was changed so that the ratio of the flow path cross-sectional area A2 of the vacuum pipe 30 to the flow path cross-sectional area A3 of the exhaust duct 40 was changed.

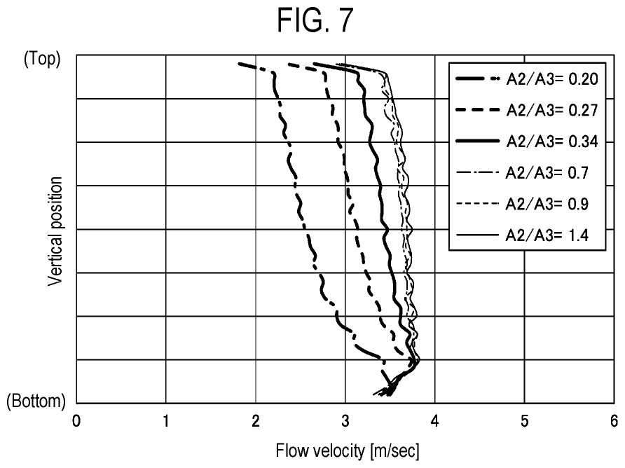

FIG. 7 is a view showing results of the simulation of the gas flow velocity distribution in the vertical direction in the interior of the reaction tube 10. In FIG. 7, the horizontal axis indicates the gas flow velocity [m/sec], and the vertical axis indicates the vertical position in the interior of the reaction tube 10. In FIG. 7, the thick one-dot chain line, the thick broken line, the thick solid line, the thin one-dot chain line, the thin broken line, and the thin solid line indicate the results when the ratio (A2/A3) of the flow path cross-sectional area A2 of the vacuum pipe 30 to the flow path cross-sectional area A3 of the exhaust duct 40 is set to 0.20, 0.27, 0.34, 0.7, 0.9, and 1.4. In FIG. 7, the thick one-dot chain line indicates a condition that the relationship of L1>L2=L3 is satisfied, and the thick broken line, the thick solid line, the thin one-dot chain line, the thin broken line, and the thin solid line indicate a condition that the relationship of L1>L2>L3 is satisfied.

As shown in FIG. 7, when the relationship L1>L2>L3 is satisfied, a difference in gas flow velocity between the upper and lower portions in the vertical direction in the interior of the reaction tube 10 is smaller than that when the relationship L1>L2=L3 is satisfied. From the results shown in FIG. 7, it can be said that when the relationship L1>L2>L3 is satisfied, the inter-plane uniformity of the gas flow velocity is improved.

As shown in FIG. 7, when the ratio of the flow path cross-sectional area A2 of the vacuum pipe 30 to the flow path cross-sectional area A3 of the exhaust duct 40 is 0.7 or more, the difference in gas flow velocity between the upper and lower portions in the vertical direction inside the reaction tube 10 is small. In contrast, when the ratio of the flow path cross-sectional area A2 of the vacuum pipe 30 to the flow path cross-sectional area A3 of the exhaust duct 40 is less than 0.7, the flow velocity in the lower portion in the vertical direction in the interior of the reaction tube 10 tends to be larger than the flow velocity in the upper portion (downward exhaust tendency). From the results of FIG. 7, it can be said that the inter-plane uniformity of the gas flow velocity is improved by setting the ratio of the flow path cross-sectional area A2 of the vacuum pipe 30 to the flow path cross-sectional area A3 of the exhaust duct 40 to 0.7 or more (by setting the flow path cross-sectional area A2 of the vacuum pipe 30 to be 0.7 times or more the flow path cross-sectional area A3 of the exhaust duct 40).

According to the present disclosure in some embodiments, it is possible to improve the in-plane uniformity of processing.

The embodiments disclosed herein should be considered to be exemplary and not limitative in all respects. The above-described embodiments may be omitted, substituted, or modified in various forms without departing from the scope and spirit of the appended claims.

What is claimed is:

1. A substrate processing apparatus, comprising:
a reaction tube having a first pipe axis extending in a vertical direction;
a vacuum pipe provided to be spaced horizontally apart from the reaction tube and having a second pipe axis parallel to the first pipe axis;
an exhaust duct having a flow path configured to bring an interior of the reaction tube into communication with an interior of the vacuum pipe; and
a housing configured to accommodate the reaction tube, the vacuum pipe, and the exhaust duct therein.

2. The substrate processing apparatus of claim 1, wherein the vacuum pipe has a cylindrical shape with a ceiling and a lower end which is opened, and
wherein the lower end of the vacuum pipe is connected to an exhaust device.

3. The substrate processing apparatus of claim 1, wherein a flow path cross-sectional area of the vacuum pipe is 0.7 times or more a flow path cross-sectional area of the exhaust duct.

4. The substrate processing apparatus of claim 1, wherein each of the reaction tube and the vacuum pipe has a cylindrical shape, and
wherein, in a cross-sectional view perpendicular to the first pipe axis and the second pipe axis, a relationship of L1>L2>L3 is satisfied, where L1 is an inner diameter of the reaction tube, L2 is an inner diameter of the vacuum pipe, and L3 is a flow path width of the exhaust duct.

5. The substrate processing apparatus of claim 1, wherein the flow path includes a plurality of divided flow paths provided to be spaced apart from each other along the vertical direction.

6. The substrate processing apparatus of claim 5, further comprising:
a substrate holder accommodated in the interior of the reaction tube,
wherein the substrate holder includes a top plate and a bottom plate provided parallel to each other,
wherein the substrate holder is configured to hold a plurality of substrates arranged in a horizontal posture in multiple stages in the vertical direction between the top plate and the bottom plate,
wherein the plurality of divided flow paths include a first divided flow path provided in a height region above the top plate of the substrate holder, and a second divided flow path provided in a height region below the top plate and above the bottom plate of the substrate holder, and
wherein a flow path cross-sectional area of the first divided flow path is smaller than a flow path cross-sectional area of the second divided flow path.

7. The substrate processing apparatus of claim 6, wherein each of the plurality of substrates held by the substrate holder is positioned at a same height as one of the plurality of divided flow paths.
